(19) United States
(12) Patent Application Publication
(10) Pub. No.: US 2022/0052130 A1
(43) Pub. Date: Feb. 17, 2022

(54) DISPLAY PANEL AND MANUFACTURING METHOD THEREOF

(71) Applicant: SHENZHEN CHINA STAR OPTOELECTRONICS SEMICONDUCTOR DISPLAY TECHNOLOGY CO., LTD., Shenzhen (CN)

(72) Inventor: Kuo GAO, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 16/639,759

(22) PCT Filed: Dec. 24, 2019
(86) PCT No.: PCT/CN2019/127907

§ 371 Date: Feb. 18, 2020

(30) Foreign Application Priority Data
Dec. 16, 2019 (CN) 201911290075.7

(51) Int. Cl. H01L 27/32; H01L 51/52; H01L 51/56

(52) U.S. Cl. CPC H01L 27/3246; H01L 27/3272; H01L 2227/323; H01L 51/56; H01L 51/5246

(57) ABSTRACT

The present disclosure provides a display panel and manufacturing method thereof, the display panel includes a TFT substrate, a flat layer, a pixel definition layer, an OLED device layer, and a light-shielding layer. The light-shielding layer disposed on a side of the pixel definition layer away from the TFT substrate, which can effectively block the light path, preventing light emitted by the OLED device layer from entering adjacent pixels after being transmitted and reflected by the transparent pixel definition layer, thereby preventing the problem of color mixing caused by light leakage between adjacent pixels.

The present disclosure relates to the field of display technologies, and more particularly, to a display panel and manufacturing method thereof.

### BACKGROUND OF INVENTION

Recently years, organic light-emitting diode (OLED) display panels have features include self-emission, wide viewing angle, short response time, high luminous efficiency, wide color gamut, thin thickness, can be used to produce large-size and flexible display panels, and simple manufacturing processes, thereby becoming very popular new flat display panel products at home and abroad.

The pixel definition layer of the traditional display panel uses transparent materials, the light emitted from the OLED device layer on the thin film transistor (TFT) substrate is transmitted and reflected multiple times in the pixel definition layer. Therefore, light enters into the area of adjacent pixels and exits outside the display panel to form a side leakage of the pixels, causes color mixing problems and affects the display effect.

In summary, it is necessary to provide a new display panel and a manufacturing method thereof to solve the above technical problems.

### SUMMARY OF INVENTION

The present disclosure provides a display panel, which can be provided with a light-shielding layer on the pixel definition layer, to solve the problem of the display panel of the prior art, that easy to cause the lateral light leakage of the pixels, causing the technical problem of color mixing.

To solve the above problems, the present disclosure provides that:

A display panel, including:

a TFT substrate;

a flat layer disposed on the TFT substrate;

a pixel definition layer disposed on the flat layer, wherein the pixel definition layer is provided with a plurality of first openings thereon, and the pixel definition layer is made of a hydrophilic material;

an OLED device layer comprising an anode, an OLED light-emitting layer, and a cathode stacked on the flat layer from bottom to top sequentially, wherein the OLED light-emitting layer is disposed in the first opening; and

a light-shielding layer disposed on a side of the pixel definition layer away from the TFT substrate.

In an embodiment of the present disclosure, the pixel definition layer is further provided with a plurality of second openings spaced apart from and disposed alternately with the plurality of first openings;

the light-shielding layer includes a first light-shielding layer and a second light-shielding layer, the first light-shielding layer covers an inner sidewall of the second opening, and the second light-shielding layer is located on a side of the first light-shielding layer away from the TFT substrate.

In an embodiment of the present disclosure, a hydrophobicity of the second light-shielding layer is gradually increased in a direction from a position close to the TFT substrate toward a position away from the TFT substrate.

In an embodiment of the present disclosure, an orthographic projection of the second light-shielding layer on the TFT substrate covers an orthographic projection of the first light-shielding layer on the TFT substrate.

In an embodiment of the present disclosure, a material of the light-shielding layer includes a black resin.

In an embodiment of the present disclosure, the display panel further includes a cover plate disposed opposite to the TFT substrate, the cover plate includes a plurality of color resist units, each color resist unit includes a plurality of color resist and a black matrix disposed between two adjacent color resists, and the black matrix is disposed corresponding to the second light-shielding layer.

In an embodiment of the present disclosure, a plurality of support pillars are provided on a side near the TFT substrate of the cover plate, and the plurality of support pillars are in contact with the second light-shielding layer.

In an embodiment of the present disclosure, the display panel further includes a protective layer disposed between the support pillar and the second light-shielding layer.

In an embodiment of the present disclosure, a peripheral region between the cover plate and the TFT substrate is further provided with a frame sealant.

In an embodiment of the present disclosure, a cross-sectional shape of the second light-shielding layer is a regular trapezoid.

The present disclosure further provides a display panel, including:

a TFT substrate;

a flat layer disposed on the TFT substrate;

a pixel definition layer disposed on the flat layer, wherein the pixel definition layer is provided with a plurality of first openings thereon,

an OLED device layer comprising an anode, an OLED light-emitting layer, and a cathode stacked on the flat layer from bottom to top sequentially, wherein the OLED light-emitting layer is disposed in the first opening; and

a light-shielding layer disposed on a side of the pixel definition layer away from the TFT substrate.

In an embodiment of the present disclosure, the pixel definition layer is further provided with a plurality of second openings spaced apart from and disposed alternately with the plurality of first openings;

the light-shielding layer includes a first light-shielding layer and a second light-shielding layer, the first light-shielding layer covers an inner sidewall of the second opening, and the second light-shielding layer is located on a side of the first light-shielding layer away from the TFT substrate.

In an embodiment of the present disclosure, a hydrophobicity of the second light-shielding layer is gradually increased in a direction from a position close to the TFT substrate toward a position away from the TFT substrate.

In an embodiment of the present disclosure, an orthographic projection of the second light-shielding layer on the TFT substrate covers an orthographic projection of the first light-shielding layer on the TFT substrate.

In an embodiment of the present disclosure, a material of the light-shielding layer comprise a black resin.

In an embodiment of the present disclosure, the display panel further includes a cover plate disposed opposite to the TFT substrate, the cover plate includes a plurality of color resist units, each color resist unit includes a plurality of color resist and a black matrix disposed between two adjacent color resists, and the black matrix is disposed corresponding to the second light-shielding layer.

In an embodiment of the present disclosure, a plurality of support pillars are provided on a side near the TFT substrate of the cover plate, and the plurality of support pillars are in contact with the second light-shielding layer.

In an embodiment of the present disclosure, the display panel further includes a protective layer disposed between the support pillar and the second light-shielding layer.

The present disclosure further includes a method of manufacturing a display panel, including the following steps:

Step S10: providing a TFT substrate, and forming a flat layer on the TFT substrate;

Step S20: forming an anode and a pixel definition layer on the flat layer, and forming a plurality of first openings and second openings distributed at intervals on the pixel definition layer;

Step S30: forming a light-shielding layer on a side of the pixel definition layer away from the TFT substrate, the light-shielding layer includes a first light-shielding layer and a second light-shielding layer, the first light-shielding layer is formed in the second opening, the second light-shielding layer is formed on a side of the first light-shielding layer away from the TFT substrate;

Step S40: forming an OLED light-emitting layer in the first opening, and forming a cathode on the pixel definition layer and the OLED light-emitting layer; and

Step S50: providing a cover plate, and arranging the cover plate and the TFT substrate to form the display panel.

In an embodiment of the present disclosure, the step S30 includes the following steps:

Step S301: depositing the light-shielding layer in the pixel definition layer and the second opening; and

Step S302: using a monotone mask to perform exposure, development, and etching processes to the light-shielding layer, to form the first light-shielding layer and the second light-shielding layer.

The beneficial effect of the present disclosure is that the present disclosure provides a display panel and manufacturing method thereof, by disposing a light-shielding layer on the pixel definition layer, the light-shielding layer includes a first light-shielding layer and a second light-shielding layer, disposing a second opening on the pixel definition layer, disposing the first light-shielding layer in the second opening, and forming the second light-shielding layer on a side of the first light-shielding layer away from the TFT substrate and disposed corresponding to the first light-shielding later, thereby preventing light emitted by the OLED device layer from entering adjacent pixels after being transmitted and reflected by the transparent pixel definition layer, thereby, preventing the problem of color mixing caused by light leakage between adjacent pixels, and improving the display effect.

### DESCRIPTION OF FIGURES

In order to more clearly illustrate the embodiments or the technical solutions in the prior art or the embodiment, the figures used in the description of the embodiments or the prior art will be briefly introduced below. Obviously, the figures in the following description are merely some embodiments of the present disclosure, for those of ordinary skill in the art, other figures may be obtained based on these figures without inventive steps.

FIG. 1 is a schematic cross-sectional structure diagram of a display panel according to an embodiment of the present disclosure.

FIG. 2 is a schematic cross-sectional structure diagram of another display panel according to an embodiment of the present disclosure.

FIG. 3 is a flowchart of a method of manufacturing a display panel according to an embodiment of the present disclosure.

FIG. 4A to 4E are flowcharts of a method of manufacturing a display panel according to an embodiment of the present disclosure.

### DETAILED DESCRIPTION OF PREFERRED EMBODIMENTS

The following descriptions of the embodiments are with reference to the attached figures to illustrate specific embodiments that can be implemented of the present disclosure. The directional terms mentioned in the present disclosure, such as “upper”, “lower”, “before”, “after”, “left”, “right”, “inside”, “outside”, “side”, etc., are only attached the directional terms used in the figures to explain and describe the present disclosure, not intend to limit the scope of the present disclosure. In the figures, the same structural components denoted by the same reference numerals.

The present disclosure is directed to a display panel and a manufacturing method thereof in the prior art which is easy to cause lateral light leakage of pixels and leads to a technical problem of color mixing. The embodiment of the present disclosure can solve this defect.

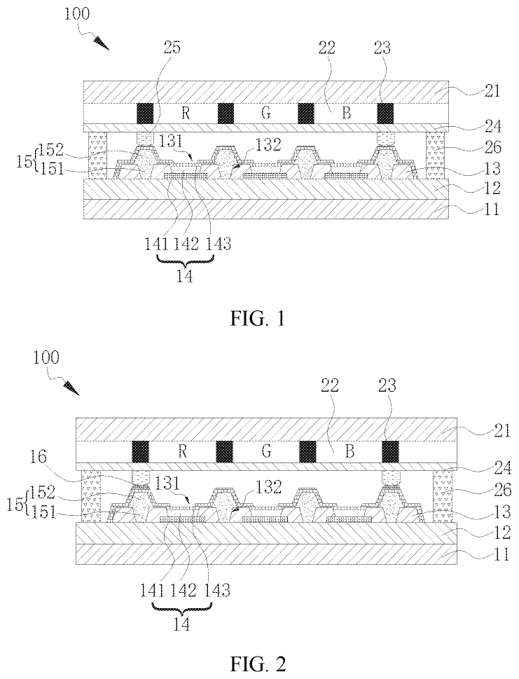

As shown in FIG. 1, a display panel 100 provided by an embodiment of the present disclosure includes a TFT substrate 11, a flat layer 12, a pixel definition layer 13, an OLED device layer 14, and a light-shielding layer 15.

The TFT substrate 11 includes a base substrate and a plurality of TFTs arranged in an array on the base substrate. In an embodiment of the present disclosure, the TFT may be a bottom-gate TFT or a top-gate TFT. Specifically, the TFT includes an active layer, a gate insulating layer, a gate, a source, and a drain (not shown in the figure) which are sequentially stacked and disposed on the base substrate.

The flat layer 12 is disposed on the TFT substrate, the pixel definition layer 13 is disposed on the flat layer 12, and the pixel definition layer 13 is provided with a plurality of first openings 131 to define the pixels. The pixel definition layer 13 defines a plurality of light-emitting areas; the OLED device layer 14 includes an anode 141, an OLED light-emitting layer 142, and a cathode 143, which are stacked on the flat layer 12 in order from bottom to top, wherein the OLED light-emitting layer 142 is provided within the first opening 131 and disposed on a portion of the anode 141 exposed through the first opening 131.

The light-shielding layer 15 is disposed on a side of the pixel definition layer 13 away from the TFT substrate 11 and located between two adjacent OLED light-emitting layers 142. To make the light-shielding layer 15 blocks light emitted from adjacent OLED light-emitting layers 142, in an embodiment of the present disclosure, the light-shielding layer 15 is made of an opaque material.

Specifically, material of the light-shielding layer 15 can be black resin.

Since the pixel defining layer 13 is generally a transparent material, part of the light emitted by the adjacent OLED light-emitting layer 142 easily passes through the pixel defining layer 13, and transmitted to the outside after being transmitted or reflected multiple times within the pixel defining layer 13, and mix colors with the light emitted by other adjacent OLED light-emitting layers 142, which affects the display effect. Further, the pixel definition layer 13 is provided with a plurality of second openings 132 spaced apart from and disposed alternately with the plurality of first openings 131, the second opening 132 is located between two adjacent OLED light-emitting layers 142.

The light-shielding layer 15 includes a first light-shielding layer 151 and a second light-shielding layer 152, wherein the first light-shielding layer 151 covers an inner sidewall of the second opening 132, and the second light-shielding layer 152 is located on a side of the first light-shielding layer 151 away from the TFT substrate 11. In an embodiment of the present disclosure, the second light-shielding layer 152 is at least partially located on the first light-shielding layer 151; part of the light emitted by the adjacent OLED light-emitting layer 142 of passing through the pixel definition layer 13 is blocked by the second light-shielding layer 152, and cannot be emitted from the pixel definition layer 13 to other pixel areas, thereby preventing the occurrence of color mixing.

Further, an orthographic projection of the second light-shielding layer 152 of the second light-shielding layer on the TFT substrate 11 covers an orthographic projection of the first light-shielding layer 151 on the TFT substrate 11, to ensure that part of the light emitted by the adjacent OLED light-emitting layer 142 of passing through the pixel definition layer 13 can be absorbed by the first light-shielding layer 151 after being transmitted, thereby further improving the display effect.

The pixel definition layer 13 is made of a hydrophilic material to ensure that when the OLED light-emitting layer 142 is printed by inkjet, ink can cover an edge of the second light-shielding layer 152 to improve the light-emitting performance; a hydrophobicity of the second light-shielding layer 152 is gradually increased in a direction from a position close to the TFT substrate 11 toward a position away from the TFT substrate 11. That is, the surface of the second light-shielding layer 152 far from the TFT substrate 11 is more hydrophobic than the surface of the second light-shielding layer 152 near the TFT substrate 11, to ensure that ink does not overflow from the second light-shielding layer 152.

It can be understood that in the embodiment of the present disclosure, superposing the pixel definition layer 13 and the second light-shielding layer 152 to prevent ink from overflowing, which is beneficial to the inkjet printing process.

In an embodiment of the present disclosure, a cross-sectional shape of the second light-shielding layer 152 is a regular trapezoid.

Further, the display panel 100 further includes a cover plate 21 disposed opposite to the TFT substrate 11. The cover plate 21 includes a plurality of color resist units. Each color resist unit includes a plurality of color resist 22, and a plurality of a black matrix 23 disposed between two adjacent color resists 22, and the black matrix 23 is disposed corresponding to the second light-shielding layer 152.

Specifically, the color resist unit includes a red color resist R, a green color resist G, and a blue color resist B. Of course, it may also include a white color resist W. In an embodiment of the present disclosure, a width of the black matrix 23 may be equal to a width of the second light-shielding layer 152, and the disposing of the black matrix 23 may also be eliminated; a color film-side flat layer 24 may also be provided on a plurality of the color resist units for protecting and planarizing the color resist unit, the color film-side flat layer 24 may be made of a transparent material.

A plurality of support pillars 25 are provided on a side near the TFT substrate 11 of the cover plate 21. The plurality of support pillars 25 are arranged at intervals by spacing one color resist unit. A lower surface of the support pillars 25 in contact with the second light-shielding layers 152 and support the cover plate 21, which is beneficial to maintain the uniformity of the thickness of the large-size display panel 100 and prevent the Newton rings occur.

A peripheral region between the cover plate 21 and the TFT substrate 11 is further provided with a frame sealant 26.

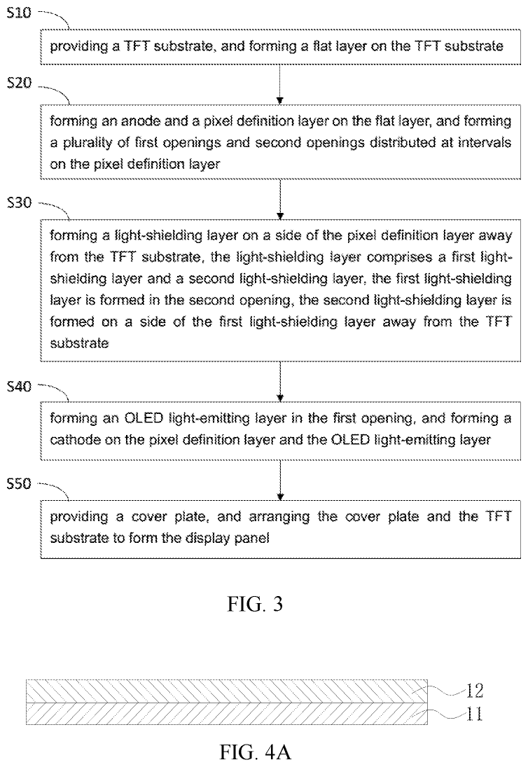

As shown in FIG. 2, the display panel further includes a protective layer disposed between the support pillar 25 and the second light-shielding layer 152. It can be understood that the cathode 143 covers the surfaces of the second light-shielding layer 152, the pixel definition layer 13, and the OLED light-emitting layer 142. The protection layer 16 can be disposed to avoid contact between the cathode 143 and the support pillar 25, which causes damage of the cathode 143 and affects the performance of the OLED device layer 14.

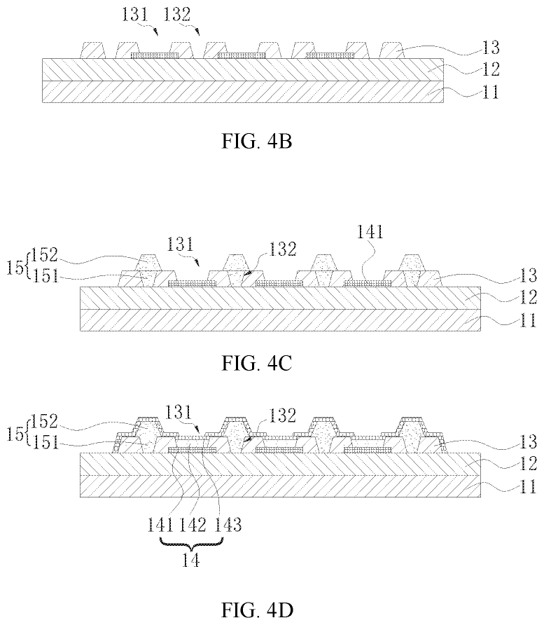

As shown in FIG. 3, an embodiment of the present disclosure further provides a method of manufacturing a display panel, including the following steps:

Step S10: Providing a TFT substrate 11, and forming a flat layer 12 on the TFT substrate 11.

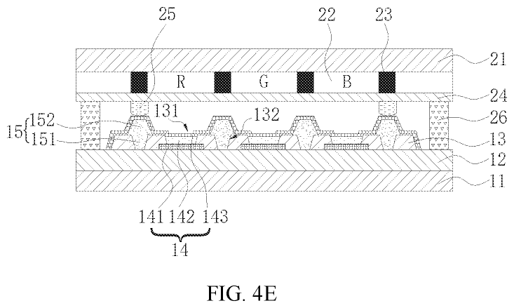

Specifically, as shown in FIG. 4A, forming a plurality of TFTs distributed in an array on the base substrate. Specifically, each of the plurality of TFTs includes an active layer, a gate insulating layer, a gate electrode, a source electrode, and a drain electrode, through-hole are formed on the flat layer 12 to expose the drain electrodes.

Step S20: forming an anode 141 and a pixel definition layer 13 on the flat layer 12, and forming a plurality of first openings 131 and second openings 132 distributed at intervals on the pixel definition layer 13.

Specifically, as shown in FIG. 4B, the anode 141 is formed on the flat layer 12, and the pixel definition layer 13 covers the flat layer 12 and the anode 141; using a monotone mask to perform exposed, development, and etching process to the pixel definition layer 13, to form a plurality of first openings 131 and second openings 132 distributed at intervals on the pixel definition layer 13, wherein exposed the anode 141 by the first opening 131.

Step S30: forming a light-shielding layer 15 on a side of the pixel definition layer 13 away from the TFT substrate 11, the light-shielding layer 15 includes a first light-shielding layer 151 and a second light-shielding layer 152, the first light-shielding layer 151 is formed in the second opening 132, the second light-shielding layer 153 is formed on a side of the first light-shielding layer 151 away from the TFT substrate 11.

Specifically, as shown in FIG. 4C, the step S30 specifically includes the following steps:

Step S301: depositing the light-shielding layer 15 in the pixel definition layer 13 and the second opening 132; and

Step S302: using a monotone mask to perform exposure, development, and etching processes on the light-shielding layer 15 to form the first light-shielding layer 151 and the second light-shielding layer 152.

Specifically, the first light-shielding layer 151 and the second light-shielding layer 152 are manufactured through the same mask, a material of the first light-shielding layer 151 and a material of the second light-shielding layer 152 are black resin.

Step S40: forming an OLED light-emitting layer in the first opening 131, and forming a cathode 143 on the pixel definition layer 13 and the OLED light-emitting layer 142.

Specifically, as shown in FIG. 4D, the OLED light-emitting layer 142 is formed in the first opening 131 by inkjet printing, forming the cathode 143 on the pixel definition layer 13 and the OLED light-emitting layer 142 by evaporation or deposition process, wherein the OLED device layer 14 is formed by sequentially stacked the anode 141, the OLED light-emitting layer 142, and the cathode 143 on the flat layer 12 from bottom to top.

Step S50: providing a cover plate 21, and arranging the cover plate 21 and the TFT substrate 11 to form the display panel.

Specifically, as shown in FIG. 4E, a plurality of color resist units and a plurality of black matrices 23 are formed on the cover plate 21, the color resist units include a plurality of color resists 22, and the black matrix 23 disposed between two adjacent color resist 22; a color film-side flat layer 24 is provided on a plurality of the color resist units for protecting and flattening the color resist unit and material of the color film-side flat layer 24 may be transparent material.

A plurality of support pillars 25 are provided on a side near the TFT substrate 11 of the cover plate 21. The plurality of support pillars 25 are arranged at intervals by spacing one color resist unit. A lower surface of the support pillars 25 in contact with the second light-shielding layers 152, a peripheral region between the cover plate 21 and the TFT substrate 11 is further provided with a frame sealant 26.

The beneficial effect of the present disclosure is that the present disclosure provides a display panel and manufacturing method thereof, by disposing a light-shielding layer on the pixel definition layer, the light-shielding layer includes a first light-shielding layer and a second light-shielding layer, disposing a second opening on the pixel definition layer, disposing the first light-shielding layer in the second opening, and forming the second light-shielding layer on a side of the first light-shielding layer away from the TFT substrate and disposed corresponding to the first light-shielding later, thereby preventing light emitted by the OLED device layer from entering adjacent pixels after being transmitted and reflected by the transparent pixel definition layer, thereby, preventing the problem of color mixing caused by light leakage between adjacent pixels, and improving the display effect.

In summary, although the present disclosure has been disclosed as above with preferred embodiments, the above-preferred embodiments are not intended to limit the present disclosure. Those skilled in the art can make various modifications without departing from the spirit and scope of the present disclosure, therefore the protection scope of the present disclosure is defined by the claims.

What is claimed is:

1. A display panel, comprising:
a TFT substrate;
a flat layer disposed on the TFT substrate;
a pixel definition layer disposed on the flat layer, wherein the pixel definition layer is provided with a plurality of first openings thereon, and the pixel definition layer is made of a hydrophilic material;
an OLED device layer comprising an anode, an OLED light-emitting layer, and a cathode stacked on the flat layer from bottom to top sequentially, wherein the OLED light-emitting layer is disposed in the first opening; and
a light-shielding layer disposed on a side of the pixel definition layer away from the TFT substrate.

2. The display panel as claimed in claim 1, wherein the pixel definition layer is further provided with a plurality of second openings spaced apart from and disposed alternately with the plurality of first openings;
the light-shielding layer comprises a first light-shielding layer and a second light-shielding layer, the first light-shielding layer covers an inner sidewall of the second opening, and the second light-shielding layer is located on a side of the first light-shielding layer away from the TFT substrate.

3. The display panel as claimed in claim 2, wherein a hydrophobicity of the second light-shielding layer is gradually increased in a direction from a position close to the TFT substrate toward a position away from the TFT substrate.

4. The display panel as claimed in claim 2, wherein an orthographic projection of the second light-shielding layer on the TFT substrate covers an orthographic projection of the first light-shielding layer on the TFT substrate.

5. The display panel as claimed in claim 1, wherein a material of the light-shielding layer comprises a black resin.

6. The display panel as claimed in claim 2, wherein the display panel further comprises a cover plate disposed opposite to the TFT substrate, the cover plate comprises a plurality of color resist units, each color resist unit comprises a plurality of color resist and a black matrix disposed between two adjacent color resists, and the black matrix is disposed corresponding to the second light-shielding layer.

7. The display panel as claimed in claim 6, wherein a plurality of support pillars are provided on a side near the TFT substrate of the cover plate, and the plurality of support pillars are in contact with the second light-shielding layer.

8. The display panel as claimed in claim 7, wherein the display panel further comprises a protective layer disposed between the support pillar and the second light-shielding layer.

9. The display panel as claimed in claim 6, wherein a peripheral region between the cover plate and the TFT substrate is further provided with a frame sealant.

10. The display panel as claimed in claim 2, wherein a cross-sectional shape of the second light-shielding layer is a regular trapezoid.

11. A display panel, comprising:
a TFT substrate;
a flat layer disposed on the TFT substrate;
a pixel definition layer disposed on the flat layer, wherein the pixel definition layer is provided with a plurality of first openings thereon,
an OLED device layer comprising an anode, an OLED light-emitting layer, and a cathode stacked on the flat layer from bottom to top sequentially, wherein the OLED light-emitting layer is disposed in the first opening; and
a light-shielding layer disposed on a side of the pixel definition layer away from the TFT substrate.

12. The display panel as claimed in claim 11, wherein the pixel definition layer is further provided with a plurality of second openings spaced apart from and disposed alternately with the plurality of first openings;
the light-shielding layer comprises a first light-shielding layer and a second light-shielding layer, the first light-shielding layer covers an inner sidewall of the second opening, and the second light-shielding layer is located on a side of the first light-shielding layer away from the TFT substrate.

13. The display panel as claimed in claim 12, wherein a hydrophobicity of the second light-shielding layer is gradually increased in a direction from a position close to the TFT substrate toward a position away from the TFT substrate.

14. The display panel as claimed in claim 12, wherein an orthographic projection of the second light-shielding layer on the TFT substrate covers an orthographic projection of the first light-shielding layer on the TFT substrate.

15. The display panel as claimed in claim 11, wherein a material of the light-shielding layer comprises a black resin.

16. The display panel as claimed in claim 12, wherein the display panel further comprises a cover plate disposed opposite to the TFT substrate, the cover plate comprises a plurality of color resist units, each color resist unit comprises a plurality of color resist and a black matrix disposed between two adjacent color resists, and the black matrix is disposed corresponding to the second light-shielding layer.

17. The display panel as claimed in claim 16, wherein a plurality of support pillars are provided on a side near the TFT substrate of the cover plate, and the plurality of support pillars are in contact with the second light-shielding layer.

18. The display panel as claimed in claim 17, wherein the display panel further comprises a protective layer disposed between the support pillar and the second light-shielding layer.

19. A method of manufacturing a display panel, comprising the following steps:
Step S10: providing a TFT substrate, and forming a flat layer on the TFT substrate;
Step S20: forming an anode and a pixel definition layer on the flat layer, and forming a plurality of first openings and second openings distributed at intervals on the pixel definition layer;
Step S30: forming a light-shielding layer on a side of the pixel definition layer away from the TFT substrate, the light-shielding layer comprises a first light-shielding layer and a second light-shielding layer, the first light-shielding layer is formed in the second opening, the second light-shielding layer is formed on a side of the first light-shielding layer away from the TFT substrate;
Step S40: forming an OLED light-emitting layer in the first opening, and forming a cathode on the pixel definition layer and the OLED light-emitting layer; and
Step S50: providing a cover plate, and arranging the cover plate and the TFT substrate to form the display panel.

20. The method of manufacturing a display panel as claimed in claim 19, wherein the step S30 comprises the following steps:
Step S301: depositing the light-shielding layer in the pixel definition layer and the second opening; and
Step S302: using a monotone mask to perform exposure, development, and etching processes to the light-shielding layer, to form the first light-shielding layer and the second light-shielding layer.
